(19) United States
(12) Patent Application Publication
(10) Pub. No.: US 2016/0062200 A1
(43) Pub. Date: Mar. 3, 2016

(54) THIN FILM TRANSISTOR ARRAY SUBSTRATE, METHOD FOR MANUFACTURING THE SAME, AND LIQUID CRYSTAL DISPLAY INCLUDING THE SAME

(71) Applicant: SAMSUNG DISPLAY CO., LTD., Yongin-City (KR)

(72) Inventors: Yang Ho Jung, Seoul (KR); Hoon Kang, Suwon-si (KR); Chul Won Park, Gwangmyeong-si (KR); Koichi Sugitani, Hwaseong-si (KR); Jin Ho Ju, Seoul (KR)

(21) Appl. No.: 14/605,853

(22) Filed: Jan. 26, 2015

(30) Foreign Application Priority Data
Sep. 3, 2014 (KR) 10-2014-0117045

(51) Int. Cl. G02F 1/1362; H01L 29/786; H01L 29/66; H01L 23/532; H01L 21/02; H01L 27/12; H01L 29/49

(52) U.S. Cl. CPC G02F 1/136286; H01L 27/124; H01L 29/78633; H01L 29/4908; H01L 23/53228; H01L 23/53257; H01L 21/02288; H01L 29/66765; H01L 29/78669; H01L 23/53209; G02F 1/136209

(57) ABSTRACT

A thin film transistor array substrate. The thin film transistor array substrate includes a stacked structure of: a light permeable substrate having a trench; a light blocking layer partially or entirely accommodated in the trench; a gate wiring formed on the light blocking layer; a semiconductor pattern layer formed on the gate wiring; and a data wiring formed on the semiconductor pattern layer.

### CROSS-REFERENCE TO RELATED APPLICATION

This application claims priority to and the benefit of Korean Patent Application No. 10-2014-0117045, filed on Sep. 3, 2014, in the Korean Intellectual Property Office, the disclosure of which is incorporated herein in its entirety by reference.

### BACKGROUND

1. Field

The following description relates to a thin film transistor array substrate, a method for manufacturing the same, and a liquid crystal display including the same.

2. Description of the Related Art

In general, a liquid crystal display panel for displaying an image includes a thin film transistor array substrate in which thin film transistors (TFTs) are formed for respective pixels to independently drive the pixels, and an opposite substrate that is opposite to (facing) the thin film transistor array substrate with a liquid crystal layer therebetween.

The liquid crystal display panel is divided into a display region in which an image is actually displayed and a non-display region that surrounds the display region. A pixel unit that includes a gate wiring, a data wiring, and a thin film transistor is formed in the display region, and a gate driving unit that applies a gate signal to a gate wiring is formed in the non-display region.

Recently, in order to reduce the area of the liquid crystal display panel, a structure that reduces the width of the non-display region has been developed.

### SUMMARY

An aspect of an embodiment of the present invention is to provide a liquid crystal display, which can improve contrast and reduce the width of a non-display region.

An aspect of an embodiment of the present invention is to provide a thin film transistor array substrate and a method for manufacturing the same, which can improve contrast.

Additional advantages, aspects, and features of the invention will be set forth in part in the description which follows and in part will become apparent to those having ordinary skill in the art upon examination of the following or may be learned from practice of the invention.

In an embodiment of the present invention, a thin film transistor array substrate is provided to include a stacked structure of: a light permeable (e.g., transparent) substrate having a trench; a light blocking layer partially or entirely accommodated in the trench; a gate wiring formed on the light blocking layer; a semiconductor pattern layer formed on the gate wiring; and a data wiring formed on the semiconductor pattern layer.

The thin film transistor array substrate may further include a gate insulating layer interposed between the gate wiring and the semiconductor pattern layer.

The thin film transistor array substrate may further include an ohmic contact layer. The ohmic contact layer may include a stacked structure interposed between the semiconductor pattern layer and the gate insulating layer.

The light blocking layer may cover the whole of one surface of the gate wiring.

The gate wiring may have a stacked structure in which a metal oxide layer is interposed between metal layers.

The gate wiring may have a stacked structure in which IZO (Indium Zinc Oxide) is interposed between titanium (Ti) and copper (Cu).

In one embodiment, a ratio of a thickness of the light blocking layer to a depth of the trench is equal to or lower than 1. In another embodiment, a ratio of a thickness of the light blocking layer to a depth of the trench exceeds 1.

In another embodiment of the present invention, a method for manufacturing a thin film transistor array substrate is provided to include: forming a trench on a light permeable substrate; forming a light blocking layer in the trench; forming a gate wiring on the light blocking layer; forming a semiconductor pattern layer on the gate wiring; and forming a data wiring on the semiconductor pattern layer.

The method may further include forming a gate insulating layer on the gate wiring before the forming of the semiconductor pattern layer.

The method may further include forming an ohmic contact layer on the semiconductor pattern layer before the forming of the data wiring.

The forming of the light blocking layer in the trench may include forming the light blocking layer on the whole of one surface of the light permeable substrate having the trench, and developing the light blocking layer so that a ratio of a thickness of the light blocking layer to a height of the trench is equal to or lower than 1.

The forming of the light blocking layer in the trench may include selectively forming the light blocking layer only on the trench using an inkjet printing technique so that a ratio of a thickness of the light blocking layer to a height of the trench is equal to or lower than 1.

The forming of the light blocking layer in the trench may include selectively forming the light blocking layer only on the trench using an inkjet printing technique so that a ratio of a thickness of the light blocking layer to a height of the trench exceeds 1.

In another embodiment of the present invention, a liquid crystal display is provided to include: a backlight unit; a cover window; a thin film transistor array substrate including a light permeable substrate interposed between the backlight unit and the cover window and having a trench, a first light blocking layer partially or entirely accommodated in the trench, a gate wiring formed on the light blocking layer, a semiconductor pattern layer formed on the gate wiring, and a data wiring formed on the semiconductor pattern layer; an opposite substrate arranged between the thin film transistor array substrate and the backlight unit and including a second light blocking layer arranged in a region that overlaps the data wiring; and a liquid crystal layer interposed between the thin film transistor array substrate and the opposite substrate.

The first light blocking layer may overlap a part of the second light blocking layer.

According to the embodiments of the present invention, at least the following effects can be achieved.

According to the thin film transistor array substrate according to an embodiment of the present invention, the contrast can be improved by forming the light blocking layer in the trench formed on the light permeable substrate and completely covering one surface of the gate wiring that is exposed to the outside. Moreover, since the liquid crystal display according to an embodiment of the present invention has the structure in which the arrangements of the thin film transistor array substrate and the opposite substrate are reverse to each other in comparison to those of the existing liquid crystal display, the problem that the bezel region is increased to hide the bent portion of the existing flexible printed circuit board can be solved, and thus the non-display region can be reduced.

The effects according to embodiments of the present invention are not limited to the contents as exemplified above, and various suitable effects are included in the description.

### BRIEF DESCRIPTION OF THE DRAWINGS

The above and other objects, features and advantages of the present invention will be more apparent from the following detailed description taken in conjunction with the accompanying drawings, in which:

FIG. 1 is a view schematically illustrating an act of preparing a light permeable substrate in a manufacturing method according to a first embodiment of the present invention;

FIGS. 2 to 5 are views schematically illustrating a process of forming a trench on the light permeable substrate of FIG. 1 using a photolithography method;

FIG. 6 is a view schematically illustrating an act of forming a light blocking layer on a front surface of the light permeable substrate of FIG. 5;

FIG. 7 is a view schematically illustrating an act of selectively forming a light blocking layer in a trench only;

FIG. 8 is a view schematically illustrating an act of forming a gate wiring;

FIG. 9 is a view schematically illustrating an act of spreading a photosensitive solution;

FIG. 10 is a view schematically illustrating an act of selectively forming a photosensitive layer in a trench only;

FIG. 11 is a view schematically illustrating an act of forming a gate wiring in a trench only through patterning of the gate wiring;

FIG. 12 is a view schematically illustrating an act of removing a photosensitive layer of a trench;

FIG. 13 is a view schematically illustrating a cross section of a thin film transistor according to the first embodiment of the present invention;

FIG. 14 is a view schematically illustrating an act of selectively forming a light blocking layer in a trench using an inkjet printing technique in a manufacturing method according to a second embodiment of the present invention;

FIG. 15 is a view schematically illustrating an act of selectively forming a photosensitive layer in a trench using an inkjet printing technique in a manufacturing method according to the second embodiment of the present invention;

FIG. 16 is a view schematically illustrating an act of forming a light blocking layer on the whole trench in a manufacturing method according to a third embodiment of the present invention;

FIG. 17 is a view schematically illustrating a cross section of a thin film transistor according to the third embodiment of the present invention;

FIG. 18 is a view schematically illustrating a step of forming a light blocking layer on the whole trench in a manufacturing method according to a fourth embodiment of the present invention;

FIG. 19 is a view schematically illustrating a cross section of a thin film transistor according to the fourth embodiment of the present invention; and

FIG. 20 is a view schematically illustrating a cross section of a liquid crystal display according to the first embodiment of the present invention.

### DETAILED DESCRIPTION

Features of the inventive concept and methods of accomplishing the same may be understood more readily by reference to the following detailed description of preferred embodiments and the accompanying drawings. The inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the inventive concept will only be defined by the appended claims.

In the drawings, the thickness of layers and regions are exaggerated for clarity. It will be understood that when an element or layer is referred to as being “on,” “connected to” or “coupled to” another element or layer, the element or layer can be directly on, connected or coupled to another element or layer, or one or more intervening elements or layers may be present. In contrast, when an element is referred to as being “directly on,” “directly connected to” or “directly coupled to” another element or layer, there are no intervening elements or layers present. As used herein, connected may refer to elements being physically, electrically, operably, and/or fluidly connected to each other.

Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “below,” “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof. Expressions such as “at least one of,” when preceding a list of elements, modify the entire list of elements and do not modify the individual elements of the list. Further, the use of “may” when describing embodiments of the present invention refers to “one or more embodiments of the present invention.” Also, the term “exemplary” is intended to refer to an example or illustration. As used herein, the terms “use,” “using,” and “used” may be considered synonymous with the terms “utilize,” “utilizing,” and “utilized,” respectively.

Hereinafter, embodiments of the present invention will be described with reference to the accompanying drawings.

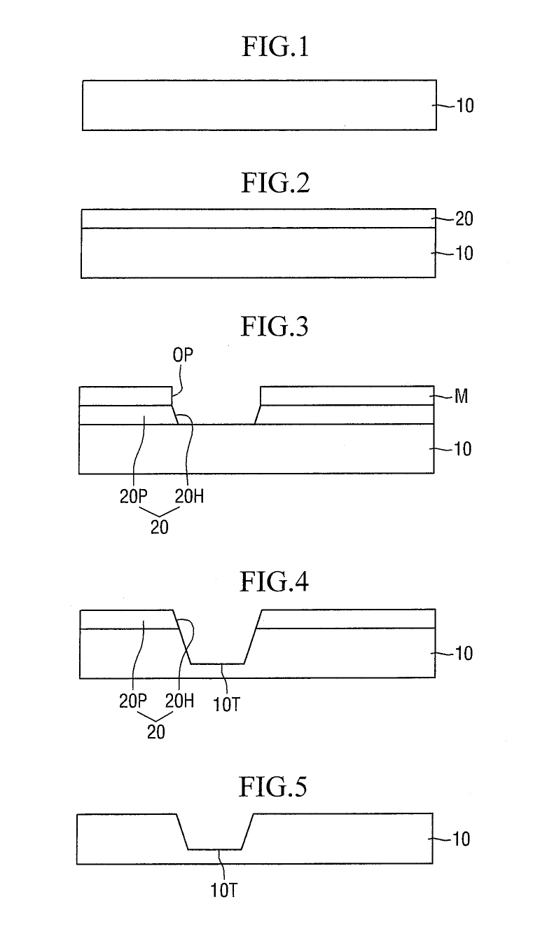

FIG. 1 schematically illustrates an act of preparing a light permeable (e.g., transparent) substrate 10 in a manufacturing method according to a first embodiment of the present invention.

The light permeable substrate 10 may be made of a material having superior light permeability. As an example, the light permeable substrate 10 may be made of glass or transparent plastic. The light permeable substrate 10 may be a transparent insulating substrate. The light permeable substrate 10 may be a rectangular flat substrate. Hereinafter, explanation will be made on the assumption that the light permeable substrate is a rectangular flat substrate. However, the light permeable substrate 10 is not limited to the rectangular flat substrate.

FIGS. 2 to 5 schematically illustrate a process of forming a trench 10T on the light permeable substrate 10 of FIG. 1 using a photolithography method.

Referring to FIG. 2, a first photosensitive layer 20 may be formed on the light permeable substrate 10 by spreading a photosensitive solution on the whole surface of the light permeable substrate 10. In the drawing, the first photosensitive layer 20 may be spread on the whole of an upper surface of the light permeable substrate 10.

Referring to FIG. 3, a first photosensitive layer pattern 20P may be formed by selectively exposing and developing the first photosensitive layer 20 using a mask M that is arranged on the upper portion of the light permeable substrate 10. A first region 20H of the first photosensitive layer 20 that is exposed through an opening OP of the mask M may be removed through exposure and development. The first region 20H, from which the first photosensitive layer is removed, may be in the shape of a through-hole that penetrates the first photosensitive layer. The first photosensitive layer pattern 20P may be formed around (e.g., to surround) the first region 20H. The first photosensitive layer pattern 20P may be separately formed around the first region 20H. The first region 20H may expose a part of the upper surface of the light permeable substrate 10. The first region 20H may be a region that overlaps the opening OP of the mask M. The first photosensitive layer pattern 20P serves as a mask for forming the trench 10T on the upper surface of the light permeable substrate 10 as shown in FIG. 4.

Referring to FIG. 4, the mask M of FIG. 3 may be removed, and the trench 10T may be formed on a part of the light permeable substrate 10 using the first photosensitive layer pattern 20P as a mask. The trench 10T may be a space that is obtained by removing a part of the light permeable substrate 10, and may be formed in a region that substantially overlaps the opening OP of the mask M.

Referring to FIG. 5, the first photosensitive layer pattern 20P that is formed on the light permeable substrate 10 is removed to manufacture the light permeable substrate 10 having the trench 10T.

The light permeable substrate 10 having the trench 10T may have a cross-sectional shape that includes a bottom surface, tapered surfaces that are tapered upwardly in a reverse symmetric shape based on the bottom surface (e.g., tapered surfaces that are tapered to become progressively wider away from one another in the present cross section view moving away from the bottom surface), an upper surface that is composed of upper planes extending from the tapered surfaces, side surfaces extending from the upper planes, and a lower surface extending from the side surfaces. Here, it should be apparent that although the tapered surfaces are shown as two opposite tapered surfaces facing one another in the present cross section view, these tapered surfaces may in a different view be a single integrated or continuous surface defining the trench 10T.

The trench 10T may be formed by selectively removing a part of the light permeable substrate 10 using a dry etching method.

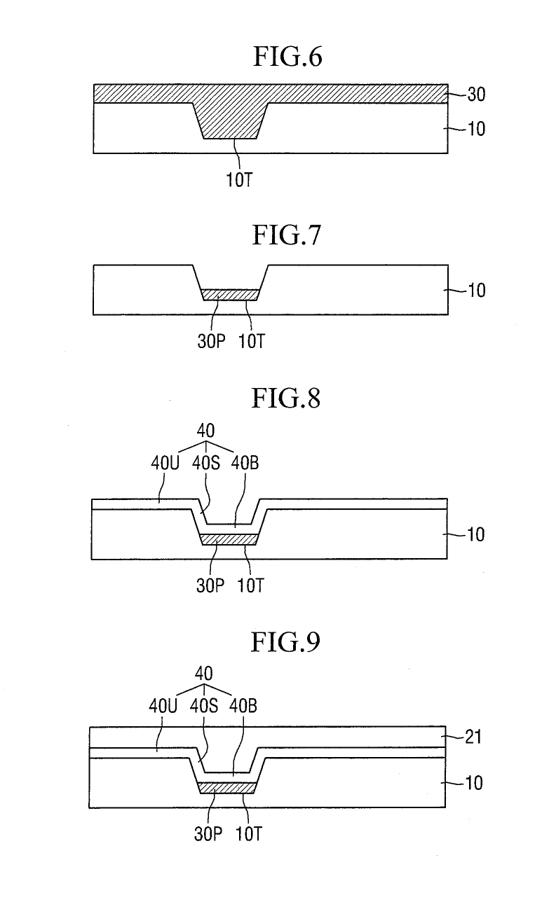

FIG. 6 schematically illustrates an act of forming a light blocking layer on a front surface of the light permeable substrate of FIG. 5.

Referring to FIG. 6, a first light blocking layer 30 may be formed on the whole of the upper surface of the light permeable substrate 10. The first light blocking layer 30 may cover the whole of the upper surface of the light permeable substrate 10. After the first light blocking layer 30 is formed, a solvent may be removed through pre-baking.

As an example, the first light blocking layer 30 may be made of a material having low refractive index and low light absorption coefficient. The low refractive index may be equal to or higher than 1.5 and equal to or lower than 2.0, and the low light absorption coefficient may be equal to or higher than 0.1 and equal to or lower than 2.0. The refractive index may be adjusted through adjustment of the contents of siloxane-based polymer and carbon black. The light absorption coefficient may be adjusted through adjustment of the contents of a pigment.

Further, the first light blocking layer 30 may be made of a material having heat resistance within a temperature range of 100° C. to 500° C. As an example, the first light blocking layer 30 may be formed to include carbon black as a pigment and siloxane-based polymer as a binder.

FIG. 7 schematically illustrates an act of selectively forming a first light blocking pattern layer 30P in a trench 10T only.

Referring to FIG. 7, the first light blocking pattern layer 30P may be slowly removed from an upper portion to a lower portion using a developing solution only without passing through an exposing process. The trench 10T provided on the light permeable substrate 10 may be divided into a first region where the first light blocking pattern layer 30P is formed and a second region where the first light blocking pattern layer 30P is not formed. In the first region, a part of the tapered surfaces that are in reverse symmetry with the bottom surface of the light permeable substrate 10 may be covered by the first light blocking pattern layer 30P. The tapered surfaces of the second region are not covered by the first light blocking pattern layer 30P. The second region is surrounded by the tapered surfaces (i.e., a remaining part of the tapered surfaces not covered by the first light blocking pattern layer 30P) and the upper surface of the first light blocking pattern layer 30P, and an upper portion of the second region is opened (exposed).

In FIG. 7, the ratio of the thickness of the first light blocking pattern layer 30P to the depth of the trench 10T is less than 1. That is, the thickness of the first light blocking pattern layer 30P is relatively smaller than the depth of the trench 10T, but is not limited thereto. In another embodiment, the ratio of the thickness of the first light blocking pattern layer 30P to the depth of the trench 10T is equal to or larger than 1. This will be described later.

The first light blocking pattern layer 30P may be formed in a similar figure to the shape of the trench 10T. The trench 10T may be formed in a reverse trapezoidal shape, and in this case, the first light blocking pattern layer 30P may be formed in a reverse trapezoidal shape.

FIG. 8 is a view schematically illustrating an act of forming a gate wiring 40.

Referring to FIG. 8, the gate wiring 40 may be formed on the upper plane of the light permeable substrate 10, from which the first light blocking layer 30 is removed, the tapered surfaces of the second region, and the upper surface of the first light blocking pattern layer 30P. In other words, a part of the gate wiring 40 may be formed in the second region of the trench 10T. The gate wiring 40 that is formed in the second region of the trench 10T may include a lower plane portion 40B and tapered portions 40S that are in reverse symmetry based on the lower plane portion 40B (e.g., tapered portions 40S that are tapered to become progressively wider away from one another in the present cross section view moving away from the from the lower plane portion 40B). Here, it should be apparent that although the tapered portions 40S are shown as two opposite tapered portions facing one another in the present cross section view, these tapered portions may in a different view be a single integrated or continuous portion.

The gate wiring 40 may include the lower plane portion 40B, the tapered portions 40S that are in reverse symmetry based on the lower plane portion, and an upper plane portion 40U formed on the upper plane of the light permeable substrate 10 to extend from the tapered portions.

The gate wiring 40 may be made of a conductive material. The conductive material may be metal. As an example, the gate wiring 40 may be made of at least one selected from the group including aluminum (Al), an aluminum alloy (AlNd), tungsten (W), chrome (Cr), titanium (Ti), and molybdenum (Mo). The gate wiring 40 includes a gate line and a gate electrode. The gate electrode is connected to the gate line and is formed in a projection shape.

The gate wiring 40 may be formed as a conductive metal layer by depositing conductive metal by sputtering or evaporation.

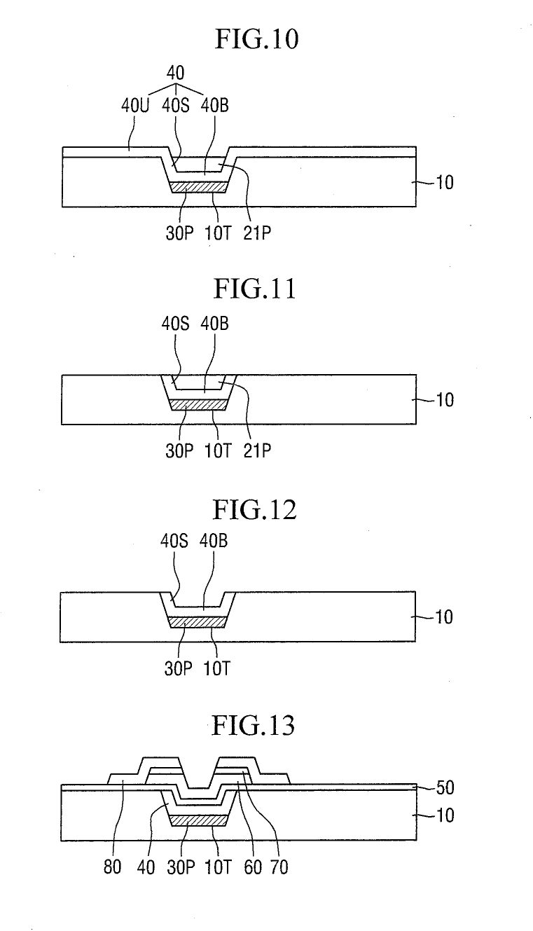

FIG. 9 schematically illustrates an act of spreading a second photosensitive layer 21. FIG. 10 schematically illustrates a step of selectively forming a photosensitive layer only in the trench 10T.

Referring to FIG. 9, the second photosensitive layer 21 may be formed on the upper plane portion 40U of the gate wiring 40, the tapered portions 40S, and the whole of the lower plane portion 40B. Referring to FIG. 10, a second photosensitive layer pattern 21P may be formed in the trench 10T. The second photosensitive layer pattern 21P may be formed on the lower plane portion 40B of the gate wiring 40 and the tapered portions 40S that extend upward from the lower plane portion 40B and are in a reverse symmetric shape (e.g., the second photosensitive layer pattern 21P become progressively larger moving away from the from the lower plane portion 40B). The second photosensitive layer 21 may be removed slowly from the upper portion to the lower portion using a developing solution without passing through an exposing process. The second photosensitive layer pattern 21P may be formed in the trench 10T by slowly removing the second photosensitive layer 21 up to the same level as the level of one surface (e.g., upper or topmost surface) of the light permeable substrate 10.

FIG. 11 schematically illustrates an act of forming a gate wiring 40 in the trench 10T only through patterning of the gate wiring 40.

The gate wiring 40 formed in the trench 10T may be patterned using a mask. The trench 10T may be filled with the first light blocking pattern layer 30P, the gate wiring 40 formed on the first light blocking pattern layer 30P, and the second photosensitive layer pattern 21P formed on the gate wiring 40.

The gate wiring 40 may be formed only in the trench 10T by removing an upper plane portion 40U of the gate wiring 40 from the upper plane of the light permeable substrate 10. The gate wiring 40 formed in the trench 10T may include a lower plane portion 40B, and tapered portions 40S that are in reverse symmetry based on the lower plane portion 40B.

FIG. 12 schematically illustrates an act of removing a second photosensitive layer pattern 21P from the trench 10T.

The lower plane portion 40B and the tapered portions 40S of the gate wiring 40 may be exposed to an outside through removal of the second photosensitive layer pattern 21P formed in the trench 10T. The lower plane portion 40B of the gate wiring 40 is entirely covered by the first light blocking pattern layer 30P. Accordingly, if light that is emitted from upper and lower portions in the drawing is incident through the light permeable substrate 10, the light is blocked by the first light blocking pattern layer 30P, and thus is unable to reach the lower plane portion 40B of the gate wiring 40.

FIG. 13 schematically illustrates a cross section of a thin film transistor according to the first embodiment of the present invention.

A thin film transistor TFT may serve as a switching device that applies/intercepts a signal to liquid crystals.

The thin film transistor array substrate may be configured to include a stacked structure of the light permeable substrate 10 having the trench 10T, the first light blocking pattern layer 30P formed in the first region of the trench 10T, the gate wiring 40 formed on the first light blocking pattern layer 30P, a gate insulating layer 50 formed on the gate wiring 40, a semiconductor layer 60 formed on the gate insulating layer 50, an ohmic contact layer 70 formed on the semiconductor layer 60, and a data wiring 80 formed on the ohmic contact layer 70.

The gate insulating layer 50 may include silicon nitride (SiNx) or silicon oxide (SiOx). A method for forming the gate insulating layer 50 is not limited. As an example, the gate insulating layer 50 may be deposited using plasma enhanced CVD (PECVD) or reactive sputtering.

The semiconductor layer 60 may be made of pure amorphous silicon (a-Si:H).

The ohmic contact layer 70 may be made of impurity-injected amorphous silicon (N+ a-Si:H). The ohmic contact layer 70 may be separated around the gate wiring 40, and a part of an upper surface of the semiconductor layer 60 may be exposed to a gap space of the separated ohmic contact layer 70.

The data wiring 80 may include a data line that crosses the gate wiring 40 to define a pixel, a source electrode that is branched from the data line to extend up to the upper portion of the semiconductor layer 60, and a drain electrode that is separated from the source electrode to face the source electrode around the gate electrode.

The data wiring 80 may be made of at least one selected from the group including molybdenum (Mo), titanium (Ti), tungsten (W), tungsten molybdenum (MoW), chrome (Cr), nickel (Ni), aluminum (Al), and an aluminum alloy (AlNd).

The source electrode and the drain electrode of the data wiring 80 may be formed on the separated ohmic contact layer 70. A channel region of the thin film transistor is formed in a section where the source electrode and the drain electrode are separated from each other.

If a high-level voltage is applied to the gate electrode of the gate wiring 40 and a data voltage is applied to the source electrode, the data voltage that is applied to the source electrode by the high-level voltage applied to the gate electrode is supplied to the drain electrode via the semiconductor layer 60.

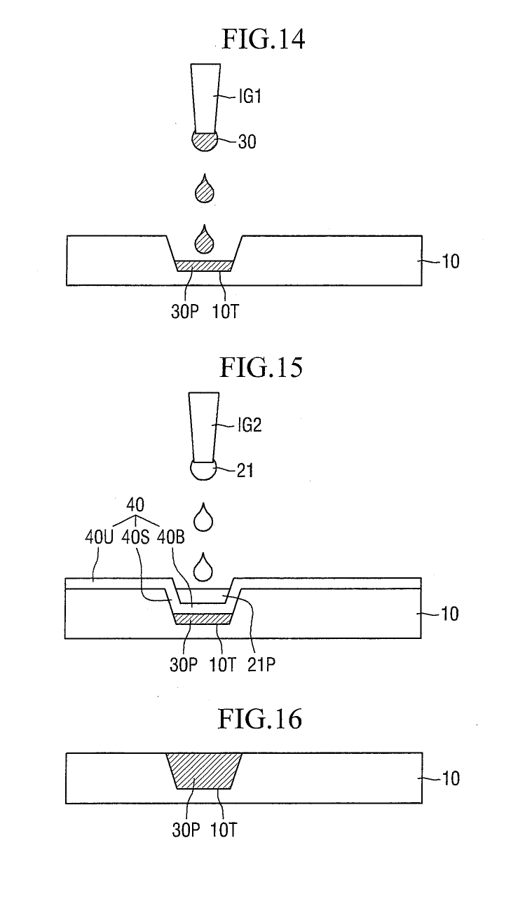

FIG. 14 schematically illustrates an act of selectively forming a light blocking pattern layer 30P in a trench 10T using an inkjet printing technique in a manufacturing method according to the second embodiment of the present invention.

Referring to FIG. 14, according to a method for manufacturing a thin film transistor array substrate according to the second embodiment of the present invention, the first light blocking pattern layer 30P may be selectively formed in the trench 10T using an inkjet printing technique.

This method according to the second embodiment is different from the method for manufacturing a thin film transistor array substrate according to the first embodiment, which forms the first light blocking pattern layer 30P only on the region of the trench 10T by forming the first light blocking layer 30 on the whole surface of the light permeable substrate 10 having the trench 10T and then developing the formed first light blocking layer 30 as illustrated in FIGS. 6 and 7.

The remaining acts, except for the acts of FIGS. 6 and 7, are the same as those of the method for manufacturing a thin film transistor array substrate according to the first embodiment.

FIG. 15 schematically illustrates an act of selectively forming a second photosensitive layer pattern 21P in a trench 10T using an inkjet printing technique in a manufacturing method according to the second embodiment of the present invention.

Referring to FIG. 15, according to a method for manufacturing a thin film transistor array substrate according to the second embodiment of the present invention, the second light blocking layer pattern 21P may be selectively formed in the trench 10T using an inkjet printing technique.

This method according to the second embodiment is different from the method for manufacturing a thin film transistor array substrate according to the first embodiment, which forms the tapered portions 40S that are in reverse symmetry with the lower plane portion 40B of the gate wiring 40 on the region of the trench 10T only by forming and developing the second photosensitive layer 21 on the whole surface of the gate wiring 40 as illustrated in FIGS. 9 and 10. The remaining acts, except for the acts of FIGS. 9 and 10, are the same as those of the method for manufacturing a thin film transistor array substrate according to the first embodiment.

FIG. 16 schematically illustrates an act of forming a first light blocking pattern layer 30P on (or filling in) the whole trench 10T in a manufacturing method according to a third embodiment of the present invention.

Referring to FIG. 16, the first light blocking pattern layer 30P may be formed on the whole trench 10T. The act of FIG. 7 is different from the step of FIG. 16 on the point that the first light blocking pattern layer 30P is formed only in the first region of the trench 10T. As illustrated in FIG. 16, the method for forming the first light blocking pattern layer 30P on the whole trench 10T may correspond to the method of FIGS. 6 and 7, which removes only the first light blocking layer 30 on the upper plane of the light permeable substrate 10 after spreading the first light blocking layer 30 on the whole surface of the light permeable substrate 10, or may correspond to the method using the inkjet printing technique as illustrated in FIG. 15.

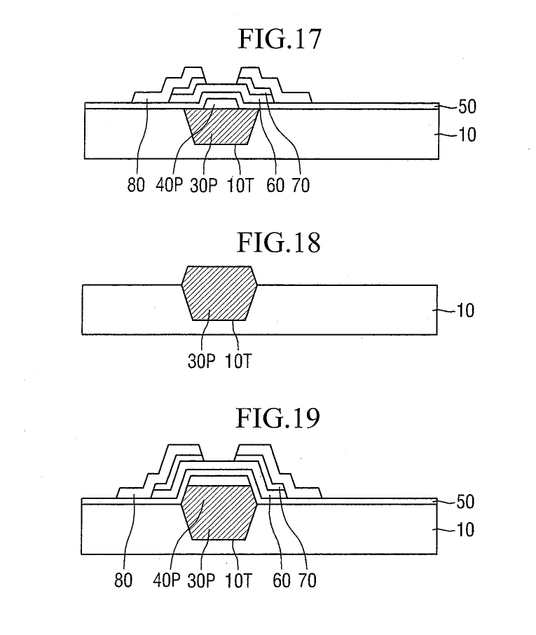

FIG. 17 schematically illustrates a cross section of a thin film transistor according to the third embodiment of the present invention.

Referring to FIG. 17, the first light blocking pattern layer 30P may be formed on the whole trench 10T, and the gate wiring 40 may be formed on the first light blocking pattern layer 30P. The ratio of the thickness of the gate wiring 40 to the depth of the trench 10T is 1.

The gate wiring 40 may be formed on the first light blocking pattern layer 30P. The gate insulating layer 50 may be formed on the gate wiring 40 and the upper plane of the light permeable substrate 10. The semiconductor layer 60 may be formed on the gate insulating layer 50. The ohmic contact layer 70 may be formed on the semiconductor layer 60, and the data wiring 80 may be formed on the ohmic contact layer 70.

The thin film transistor array substrate of FIG. 17 is different from the thin film transistor array substrate of FIG. 13 on the point that the gate wiring 40 is not composed of the tapered portions 40S that are in reverse symmetry with the lower plane portion 40B. Further, the thin film transistor array substrate of FIG. 17 is different from the thin film transistor array substrate of FIG. 13 on the point that the gate wiring 40 is formed in a convex shape. Since the gate wiring 40 is formed in a convex shape, the gate insulating layer 50 and the semiconductor layer 60, which are formed on the gate wiring 40, may have a convex shape in a region that overlaps the gate wiring 40.

FIG. 18 schematically illustrates an act of forming a first light blocking pattern layer on the whole trench 10T in a manufacturing method according to a fourth embodiment of the present invention.

Referring to FIG. 18, the first light blocking pattern layer 30P may include a body portion that fills the whole trench 10T and a projection portion that is formed to project from the body portion based on the plane of the light permeable substrate 10. The act of FIG. 18 is different from the step of FIG. 7, which forms the first light blocking pattern layer 30P only in the first region of the trench 10T, on the point that the first light blocking pattern layer 30P includes the body portion that fills the whole trench 10T and the projection portion that projects from the body portion.

As illustrated in FIG. 18, the method for forming the first light blocking pattern layer 30P on the whole trench 10T may correspond to the method of FIGS. 6 and 7, which removes only the first light blocking layer 30 on the upper plane of the light permeable substrate 10 after spreading the first light blocking layer 30 on the whole surface of the light permeable substrate 10, or may correspond to the method using the inkjet printing technique as illustrated in FIG. 15.

FIG. 19 schematically illustrates a cross section of a thin film transistor according to the fourth embodiment of the present invention.

Referring to FIG. 19, according to the thin film transistor array substrate according to the third embodiment of the present invention, the first light blocking pattern layer 30P may project convexly based on one surface of the light permeable substrate 10. The first light blocking pattern layer 30P may include a body portion that fills the whole trench 10T and a projection portion that projects from the body portion. The gate wiring 40 may be formed on the projection portion, and unlike the gate wiring illustrated in FIG. 13 or 18, the gate wiring 40 may be formed on an upper portion as compared with one surface of the light permeable substrate 10. Unlike the configuration illustrated in FIG. 13, the gate insulating layer 50 and the semiconductor layer 60 may have a convex shape in a region in which the semiconductor layer 60 overlaps the gate wiring 40.

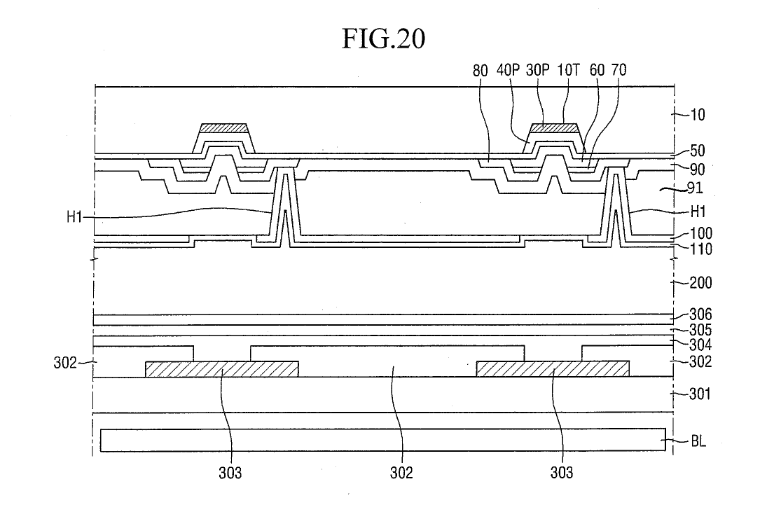

FIG. 20 schematically illustrates a cross section of a liquid crystal display according to the first embodiment of the present invention.

In the liquid crystal display according to the first embodiment of the present invention, a thin film transistor array substrate may be arranged on an upper portion of a backlight unit BL, and an opposite substrate may be interposed between the thin film transistor array substrate and the backlight unit BL.

The opposite substrate may be a color filter substrate having a color filter layer.

The thin film transistor array substrate may include a stacked structure of the light permeable substrate 10 having the trench 10T, the first light blocking pattern layer 30P formed in the trench 10T, the gate wiring formed on the first light blocking pattern layer 30P, the gate insulating layer 50 formed on the gate wiring, the semiconductor layer 60 formed on the gate insulating layer 50, the ohmic contact layer 70 formed on the semiconductor layer 60, and the data wiring 80 formed on the ohmic contact layer 70. This structure has been described.

Further, the thin film transistor array substrate may further include a first insulating layer 90, a second insulating layer 91, a pixel electrode 100, and a first alignment layer 110.

The first insulating layer 90 is a protection layer of the thin film transistor TFT, and may be formed by forming a silicon oxide (SiO₂) layer, a silicon nitride (SiNx) layer, or a double layer thereof on the thin film transistor TFT and the gate insulating layer 50.

The second insulating layer 91 may be formed by spreading an organic material, such as acryl resin or BCB, on the first insulating layer 90 in a spin coating method.

Through patterning of the first insulating layer 90 and the second insulating layer 91 of the display region using a mask, a contact hole H1 is formed to expose a part of the surface of the drain electrode of the data wiring 80.

The pixel electrode 100 may be formed on the second insulating layer 91. The pixel electrode 100 may be electrically connected to the drain electrode through the contact hole H1. The pixel electrode 100 may be formed by forming a transparent conductive layer by depositing a transparent conductive material, such as ITO (Indium Tin Oxide), on the second insulating layer 91 through sputtering or vapor deposition, patterning the transparent conductive layer using a mask, and electrically connecting the patterned transparent conductive layer to the drain electrode through the contact hole H1 on the second insulating layer 91 in the display region.

The pixel electrode 100 may be provided in a region that corresponds to the color filter layers 302. The pixel electrode 100 may be formed and patterned at set or predetermined intervals in a region that overlaps the color filter layers 302. The first alignment layer 110 may be provided on the pixel electrode 100 and the second insulating layer 91 for easy guidance of liquid crystal arrangements.

The first alignment layer 110 may be interposed between the thin film transistor array substrate and a liquid crystal layer 200. Specifically, the first alignment layer 110 may be formed on the pixel electrode 100. The first alignment layer 110 may be made of polyimide-based polymer.

A transparent insulating (or opposite) substrate 301 of a color filter substrate may include a display region where an image is displayed and a non-display region that surrounds the display region. The transparent insulating substrate 301 may be made of a transparent material. For example, the transparent insulating substrate 301 may be made of glass or transparent plastic. On the transparent insulating substrate 301, a second light blocking layer 303 that is patterned to be spaced apart at set or predetermined intervals may be provided.

The second light blocking layer 303 may be provided in a region that corresponds to the thin film transistor TFT, the gate wiring 40, and the data wiring 80 of the thin film transistor array substrate in order to intercept light leakage. A part of the second light blocking layer 303 may overlap a part of the first light blocking pattern layer 30P.

The second light blocking layer 303 may be also provided between the color filter layers 302 to prevent color mixing between the color filter layers 302. The second light blocking layer 303 may be made of metal, and for example, chrome (Cr), chrome oxide (CrOx), or a double layer thereof.

Between the second light blocking layers 303, red (R), green (G), and blue (B) color filter layers 302, which respectively filter light of specific wavelength bands, may be provided. The color filter layers 302 may include acryl resin and pigments. The color filter layers 302 may be classified into red (R), green (G), and blue (B) color filter layers according to the kind of pigments that implement colors.

An overcoat layer 304 may be additionally provided on the second light blocking layer 303 and the color filter layers 302. The overcoat layer 304 may be provided for protection of the color filter layers 302, surface planarization, and improvement of adhesive force with a common electrode 305, and may be made of, for example, acrylic resin.

The common electrode 305 may be provided on the overcoat layer 304. The common electrode 305 may be formed of a transparent conductive material. For example, the common electrode 305 may be made of ITO (indium Tin Oxide) and/or IZO (Indium Zinc Oxide). On the common electrode 305, a second alignment layer 306 may be provided for easy guidance of the liquid crystal arrangements.

The second alignment layer 306 may be provided on the common electrode 305. The second alignment layer 306 may cover the common electrode 305 and the second light blocking layer 303. The second alignment layer 306 may be interposed between the color filter substrate and the liquid crystal layer 200. The second alignment layer 306 may be made of polyimide-based polymer.

The liquid crystal layer 200 may be interposed between the thin film transistor array substrate and the color filter substrate.

While the invention has been particularly shown and described with reference to exemplary embodiments thereof, it will be understood by those of ordinary skill in the art that various suitable modifications and/or changes may be made therein without departing from the spirit and scope of the invention as defined by the following claims, and equivalents thereof. The exemplary embodiments should be considered in a descriptive sense only and not for purposes of limitation.

What is claimed is:

1. A thin film transistor array substrate comprising a stacked structure of:
a light permeable substrate having a trench;
a light blocking layer partially or entirely accommodated in the trench;
a gate wiring on the light blocking layer;
a semiconductor pattern layer on the gate wiring; and
a data wiring on the semiconductor pattern layer.

2. The thin film transistor array substrate of claim 1, further comprising a gate insulating layer between the gate wiring and the semiconductor pattern layer.

3. The thin film transistor array substrate of claim 2, further comprising an ohmic contact layer,
wherein the ohmic contact layer comprises a stacked structure between the semiconductor pattern layer and the gate insulating layer.

4. The thin film transistor array substrate of claim 1, wherein the light blocking layer covers the whole of one surface of the gate wiring.

5. The thin film transistor array substrate of claim 1, wherein the gate wiring has a stacked structure in which a metal oxide layer is between metal layers.

6. The thin film transistor array substrate of claim 1, wherein the gate wiring has a stacked structure in which IZO (Indium Zinc Oxide) is between titanium (Ti) and copper (Cu).

7. The thin film transistor array substrate of claim 1, wherein a ratio of a thickness of the light blocking layer to a depth of the trench is equal to or lower than 1.

8. The thin film transistor array substrate of claim 1, wherein a ratio of a thickness of the light blocking layer to a depth of the trench exceeds 1.

9. The thin film transistor array substrate of claim 1, wherein the light blocking layer is partially accommodated in the trench.

10. The thin film transistor array substrate of claim 1, wherein the light blocking layer is entirely accommodated in the trench.

11. The thin film transistor array substrate of claim 1, wherein the light blocking layer has a refractive index of 1.5 to 2.0.

12. The thin film transistor array substrate of claim 1, wherein the light blocking layer has a light absorption coefficient of 0.1 to 2.0.

13. A method for manufacturing a thin film transistor array substrate, the method comprising:
forming a trench on a light permeable substrate;
forming a light blocking layer in the trench;
forming a gate wiring on the light blocking layer;
forming a semiconductor pattern layer on the gate wiring; and
forming a data wiring on the semiconductor pattern layer.

14. The method of claim 13, further comprising forming a gate insulating layer on the gate wiring before the forming of the semiconductor pattern layer.

15. The method of claim 13, further comprising forming an ohmic contact layer on the semiconductor pattern layer before the forming of the data wiring.

16. The method of claim 13, wherein the forming of the light blocking layer in the trench comprises forming the light blocking layer on the whole of one surface of the light permeable substrate having the trench, and developing the light blocking layer so that a ratio of a thickness of the light blocking layer to a height of the trench is equal to or lower than 1.

17. The method of claim 13, wherein the forming of the light blocking layer in the trench comprises selectively forming the light blocking layer only on the trench using an inkjet printing technique so that a ratio of a thickness of the light blocking layer to a height of the trench is equal to or lower than 1.

18. The method of claim 13, wherein the forming of the light blocking layer in the trench comprises selectively forming the light blocking layer only on the trench using an inkjet printing technique so that a ratio of a thickness of the light blocking layer to a height of the trench exceeds 1.

19. A liquid crystal display comprising:
a backlight unit;
a cover window;
a thin film transistor array substrate comprising a light permeable substrate between the backlight unit and the cover window and having a trench, a first light blocking layer partially or entirely accommodated in the trench, a gate wiring on the light blocking layer, a semiconductor pattern layer on the gate wiring, and a data wiring on the semiconductor pattern layer;
an opposite substrate arranged between the thin film transistor array substrate and the backlight unit and comprising a second light blocking layer arranged in a region that overlaps the data wiring; and
a liquid crystal layer between the thin film transistor array substrate and the opposite substrate.

20. The liquid crystal display of claim 19, wherein the first light blocking layer overlaps a part of the second light blocking layer.
